(19) United States
(12) Patent Application Publication
(10) Pub. No.: US 2026/0068136 A1
(43) Pub. Date: Mar. 5, 2026

(54) MEMORY DEVICE AND MANUFACTURING METHOD THEREOF

(71) Applicant: NANYA TECHNOLOGY CORPORATION, New Taipei City (TW)

(72) Inventor: Chun-Heng WU, New Taipei City (TW)

(21) Appl. No.: 18/823,646

(22) Filed: Sep. 3, 2024

(51) Int. Cl. H10B 12/00

(52) U.S. Cl. CPC H10B 12/482; H10B 12/02

(57) ABSTRACT

A manufacturing method of a memory device includes forming a bit line structure over a substrate, conformally forming a first spacer layer over the bit line structure, performing a surface treatment to an upper portion of the first spacer layer, in which an oxygen concentration of the upper portion of the first spacer layer is higher than an oxygen concentration of a lower portion of the first spacer layer after the surface treatment, removing the upper portion of the first spacer layer, forming a contact structure adjacent to the bit line structure, and forming a landing pad over the contact structure and the bit line structure.

### BACKGROUND

### FIELD OF DISCLOSURE

The present disclosure relates to a memory device and a manufacturing method thereof.

### DESCRIPTION OF RELATED ART

A typical dynamic random access memory (DRAM) memory cell incorporates a capacitor and a transistor in which the capacitor temporarily stores data based on the charged state of the capacitor. A bit line is electrically connected to a source region of the transistor, and a word line is electrically connected to a gate region of the transistor. While semiconductor dimension shrink and density increase, aspect ratio of semiconductor structure arises, which would cause difficulty in deposition gap fill performance.

### SUMMARY

Some embodiments of the present disclosure provide a manufacturing method of a memory device, including forming a bit line structure over a substrate, conformally forming a first spacer layer over the bit line structure, performing a surface treatment to an upper portion of the first spacer layer, in which an oxygen concentration of the upper portion of the first spacer layer is higher than an oxygen concentration of a lower portion of the first spacer layer after the surface treatment, removing the upper portion of the first spacer layer, forming a contact structure adjacent to the bit line structure, and forming a landing pad over the contact structure and the bit line structure.

In some embodiments, performing the surface treatment includes performing an oxygen-containing plasma treatment or a hydrogen-containing plasma treatment to the upper portion of the first spacer layer.

In some embodiments, a silicon concentration of the upper portion of the first spacer layer is lower than a silicon concentration of a lower portion of the first spacer layer after the surface treatment.

In some embodiments, the surface treatment is performed with a tilted angle.

In some embodiments, the manufacturing method further includes conformally forming a second spacer layer over the first spacer layer after performing the surface treatment, forming a photoresist layer covering a lower portion of the second spacer layer, in which an upper portion of the second spacer layer is exposed by the photoresist layer, and removing the upper portion of the second spacer layer.

In some embodiments, the upper portion of the second spacer layer and the upper portion of the first spacer layer are removed at the same time.

In some embodiments, the manufacturing method further includes conformally forming a third spacer layer over the bit line structure and the second spacer layer after removing the upper portion of the first spacer layer and the upper portion of the second spacer layer, in which an upper portion of the third spacer layer is in contact with the bit line structure.

In some embodiments, the second spacer layer is cladded by a lower portion of the third spacer layer and the first spacer layer.

In some embodiments, the landing pad is spaced apart from the first spacer layer.

In some embodiments, a bottom of the landing pad is higher than a top end of the first spacer layer.

Some embodiments of the present disclosure provide a memory device including a bit line structure, a bit line spacer, and a landing pad. The bit line spacer along a sidewall of the bit line structure and includes a first spacer layer in contact with a lower portion of the sidewall of the bit line structure, a second spacer layer along a sidewall of the first spacer layer, and a third spacer layer along a sidewall of the second spacer layer, in which the third spacer layer extends to an upper portion of the sidewall of the bit line structure. The landing pad is over the bit line structure.

In some embodiments, the third spacer layer is in contact with a top end of the first spacer layer.

In some embodiments, an interface between the first spacer layer and the bit line structure is aligned with an interface between the third spacer layer and the bit line structure.

In some embodiments, a top end of the first spacer layer is substantially level with a top end of the second spacer layer.

In some embodiments, the landing pad is spaced apart from the first spacer layer.

In some embodiments, a bottom surface of the landing pad is higher than a top end of the first spacer layer.

In some embodiments, a top end of the first spacer layer is lower than a top surface of the bit line structure.

In some embodiments, the third spacer layer vertically overlaps the first spacer layer.

In some embodiments, the third spacer layer has a portion vertically between the landing pad and the first spacer layer.

In some embodiments, the first spacer layer and the third spacer layer are made of different materials.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a circuit diagram of the memory device.

FIG. 2 illustrates a top view of a manufacturing method of the memory device in some embodiments of the present disclosure.

FIGS. 3-11 illustrate cross-section views taken along line A-A’ of the memory device in FIG. 2.

FIG. 12 illustrates a top view of a memory device in some embodiments of the present disclosure.

FIGS. 13 and 14 illustrate cross-section views taken along line A-A’ and B-B’ respectively of the memory device in FIG. 12.

FIG. 15 illustrates a top view of a memory device in some embodiments of the present disclosure.

FIGS. 16 and 17 illustrate cross-section views taken along line A-A’ and B-B’ respectively of the memory device in FIG. 15.

FIG. 18 illustrates a top view of a memory device in some embodiments of the present disclosure.

FIGS. 19 and 21 illustrate cross-section views taken along line A-A’ of the memory device in FIG. 18.

FIG. 20 illustrates cross-section views taken along line B-B’ of the memory device in FIG. 18.

FIG. 22 illustrates a top view of a memory device in some embodiments of the present disclosure.

FIG. 23 illustrate a cross-section view taken along line A-A’ of the memory device in FIG. 22.

### DETAILED DESCRIPTION

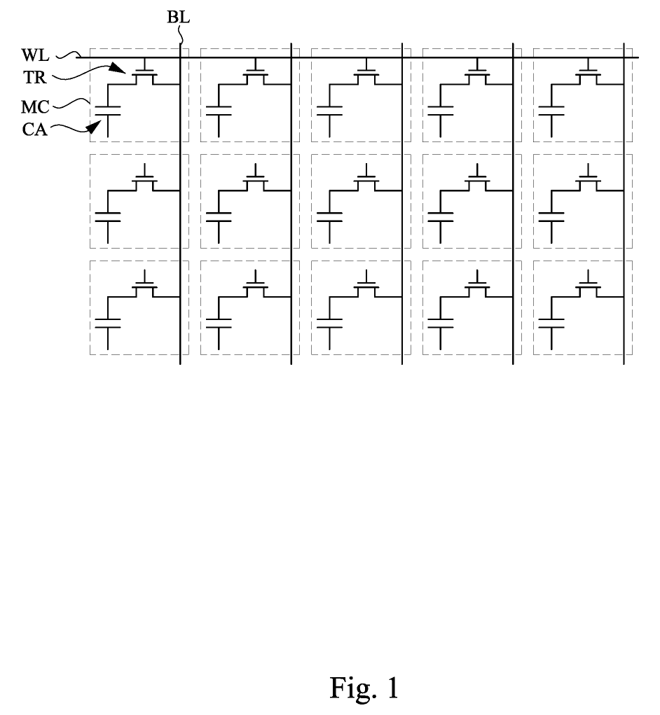

FIG. 1 illustrates a circuit diagram of the memory device. Referring to FIG. 1, the memory device (e.g., dynamic random access memory, DRAM) may include a plurality of memory cells MC. A typical DRAM memory cell incorporates a capacitor CA and a transistor TR in which the capacitor CA temporarily store data based on the charged state of the capacitor CA. The capacitor CA is electrically connected to a source/drain region of the transistor TR, a bit line BL is electrically connected to the other source/drain region of the transistor TR, and a word line WL is electrically connected to a gate region of the transistor TR. In the present disclosure, we focus on the manufacturing process of the bit lines and the capacitors. The manufacturing process of the word lines and the transistors will not be mentioned in the present disclosure.

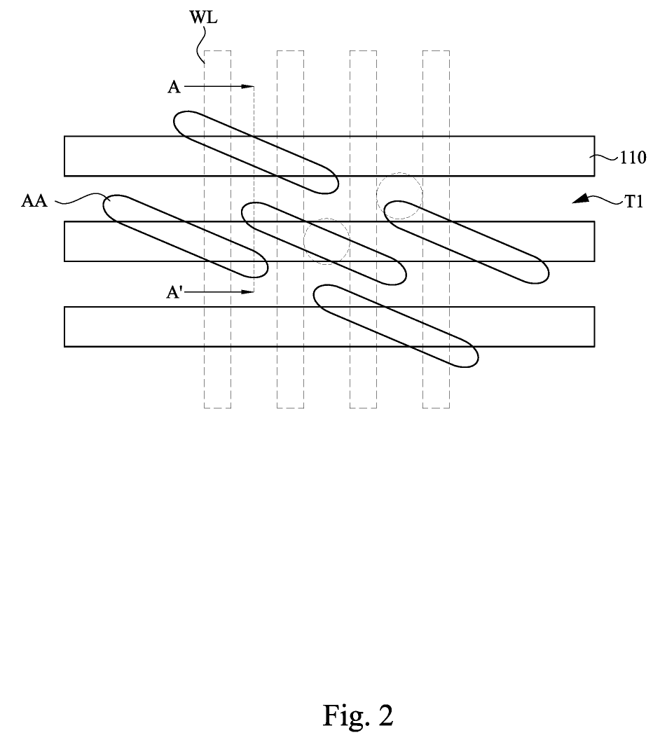

FIG. 2 illustrates a top view of a manufacturing method of the memory device in some embodiments of the present disclosure. The memory device includes active areas AA, word lines WL, and bit line structures 110. The word lines WL are over the active areas AA, and the bit line structures 110 are over the word lines WL. The word lines WL and the bit line structures 110 are along different direction. For example, the longitudinal direction of the word lines WL is perpendicular to the longitudinal direction of the bit line structures 110. The word lines WL divide each of the active areas AA into three regions. The regions at two ends of the active area AA will be connected to capacitors, and the region in the middle is connected to the bit line structure 110.

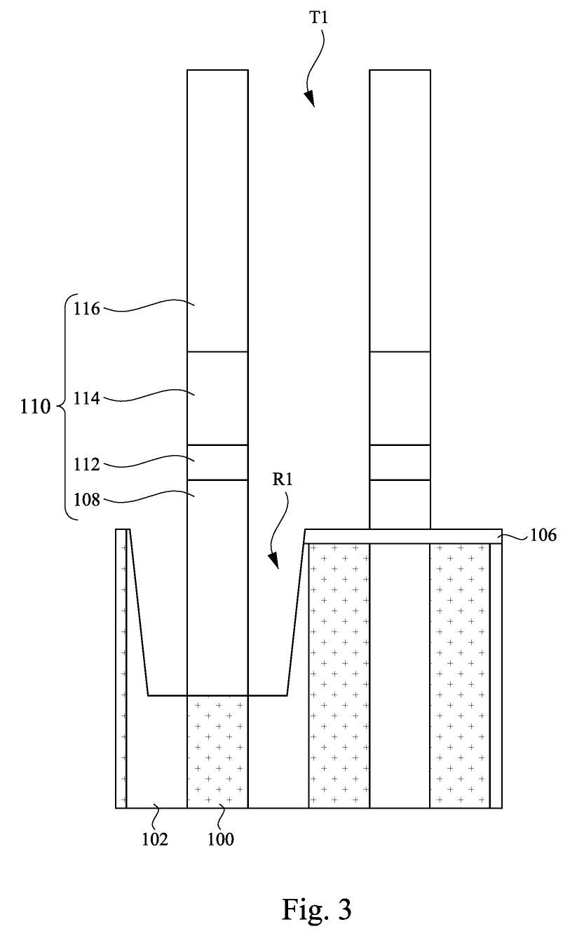

FIGS. 3-11 illustrate cross-section views taken along line A-A’ of the memory device in FIG. 2. It is noted that word line WL are not shown in FIGS. 3-11. Referring to FIG. 3, a substrate 100 is provided. Isolation structures 102 are formed in the substrate 100 and define active areas AA in FIG. 2 in the substrate 100. A dielectric layer 106 is formed over the substrate 100 and the isolation structures 102. A recess R1 may be formed in the substrate 100 and the isolation structures 102, which are not covered by the dielectric layer 106. The substrate 100 may be made of semiconductor, such as silicon. The isolation structures 102 may be made of silicon oxide, silicon nitride, or the like. The dielectric layer 106 may be made of silicon oxide, silicon nitride, or the like.

Subsequently, bit line contacts 108 and bit line structures 110 are formed over the substrate 100 and the dielectric layer 106. The bit line structures 110 are over the bit line contacts 108, and each of the bit line structures 110 includes a conductive layer 112, a conductive layer 114 over the conductive layer 112, and a cap layer 116 over the conductive layer 114. The bit line contacts 108 and the bit line structures 110 may be formed by, for example, sequentially forming conductive material layers, and a cap material layer over the substrate 100. Subsequently, the conductive material layers and the cap material layer are patterned into the bit line contacts 108 and the bit line structures 110 including conductive layers 112, the conductive layers 114, and the cap layers 116. The adjacent bit line structures 110 define a trench T1. In some embodiment, the width of the trench T1 is between 30 nm and 50 nm. In some embodiment, the width of the bit line structure 110 is between 8 nm and 12 nm. In some embodiments, the bit line contacts 108 may be made of polysilicon. The conductive layers 112 may be made of metal nitride, such as titanium nitride. The conductive layers 114 may be made of metal, such as tungsten. The cap layers 116 may be made of dielectric material, such as silicon nitride. In some embodiments, a portion of the bit line structures 110 may be formed in the recess R1.

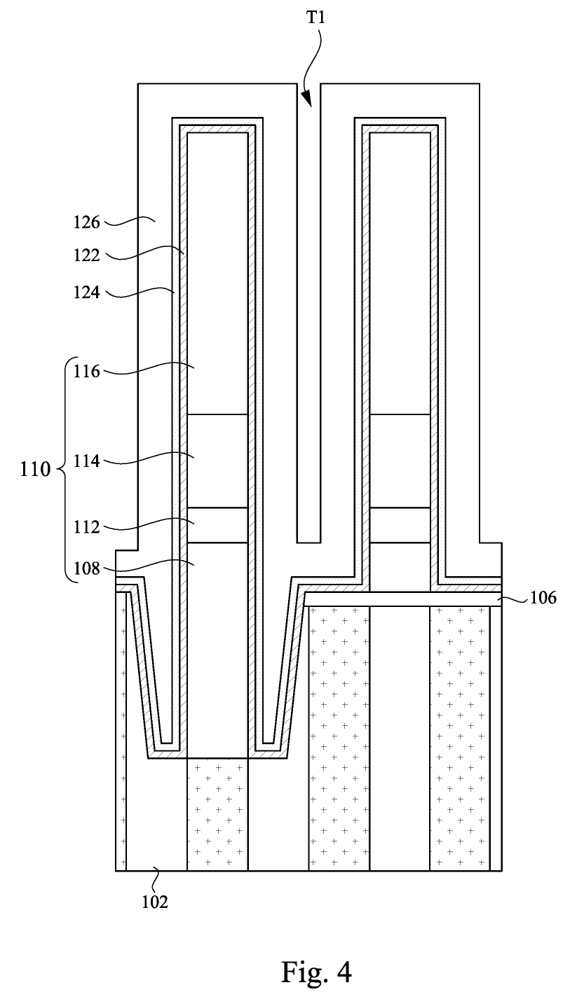

Referring to FIG. 4, a spacer layer 122, a stop etch layer 124 and a filling layer 126 are sequentially formed over the substrate 100, the isolation structures 102, the dielectric layer 106, and the bit line structures 110. Specifically, the spacer layer 122 may be conformally formed over the bit line structures 110 and lining the recess R1. Subsequently, a surface treatment is performed to the spacer layer 122, such that the outer portion of the spacer layer 122 is converted into the stop etch layer 124. Subsequently, the filling layer 126 is conformally formed over the stop etch layer 124. The filling layer 126 is thicker than the spacer layer 122 and the stop etch layer 124, and the filling layer 126 fills the recess R1. The spacer layer 122, the stop etch layer 124 and the filling layer 126 are made of dielectric material. In some embodiments, the spacer layer 122 and the filling layer 126 are made of silicon nitride, and the stop etch layer 124 is made of silicon oxide. In some other embodiments, the spacer layer 122 is made of low-k material, such as SiC, SiCO, SiCN, and the stop etch layer 124 may be omitted. In some embodiments, the thickness of the spacer layer 122 is between 4 nm and 6 nm.

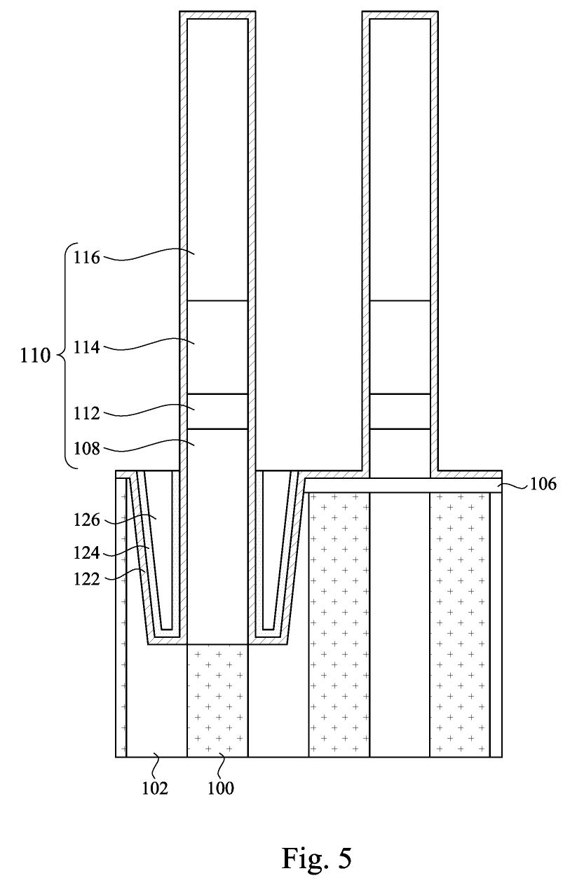

Referring to FIG. 5, an etching process is performed to remove a portion of the stop etch layer 124 and the filling layer 126 over the dielectric layer 106. The portion of the stop etch layer 124 and the filling layer 126 in the recess R1 still remains after the etching process is complete. The stop etch layer 124 may protect the spacer layer 122 from being etched by the etching process, and thus the spacer layer 122 still remains after the etching process is complete. In some embodiments, the etching process may be a wet etching process using hot phosphoric acid as etchant.

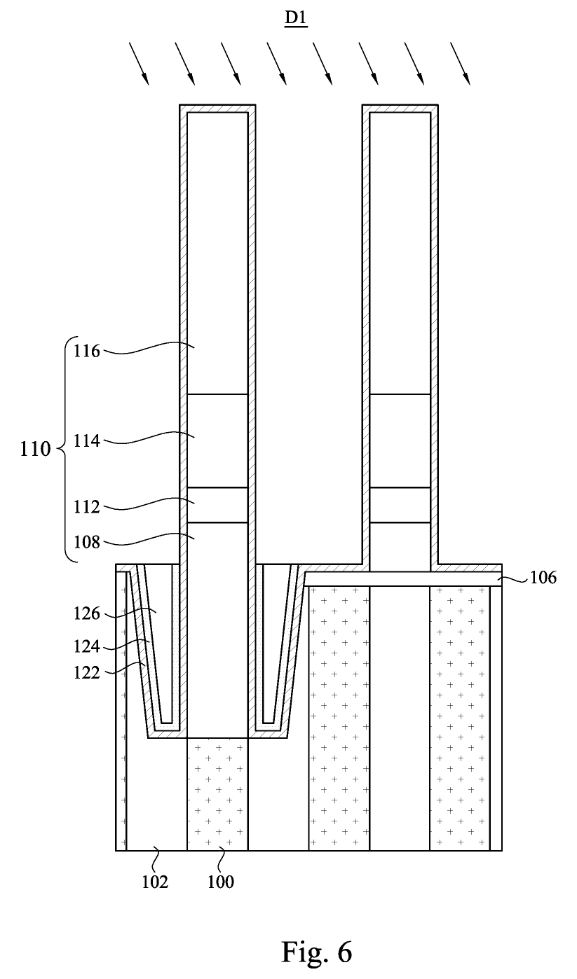

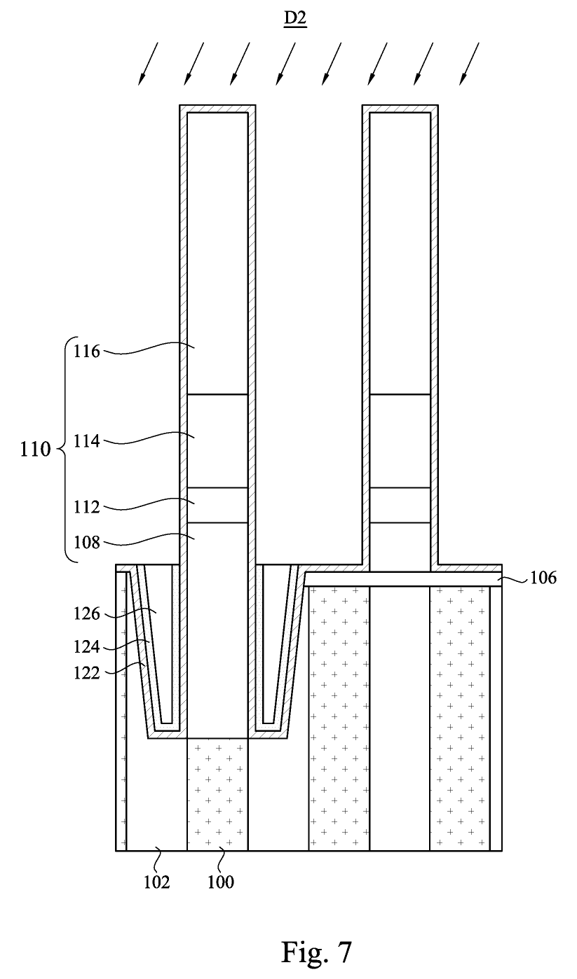

Referring to FIGS. 6 and 7, a surface treatment is performed to an upper portion of the spacer layer 122 to modify the properties of the spacer layer 122. Specifically, the surface treatment may be an oxygen-containing plasma treatment, a hydrogen-containing plasma treatment, an oxygen-containing implant process or a hydrogen-containing implant process, and the surface treatment is performed with a tilted angle. That is, an incident direction of the implants or plasma may be inclined to a normal line of the substrate 100. In some embodiments, the tilted angle may be in a range from about 25^{o} to 45^{o}. In some embodiments, the surface treatment may be firstly performed in first direction D1 in FIG. 6, and then the surface treatment may be performed in the second direction D2 in FIG. 7. Since the aspect ratio of the trench T1 between the bit line structures 110 are high, the surface treatment does not substantially affect the properties of the lower portion of the spacer layer 122. After the surface treatment is complete, the oxygen concentration of the upper portion of the spacer layer 122 is higher than the oxygen concentration of a lower portion of the spacer layer 122, and the silicon concentration of the upper portion of the spacer layer 122 is lower than the silicon concentration of a lower portion of the spacer layer 122. In some other embodiments where the spacer layer 122 is a carbon-containing layer, the carbon concentration of the upper portion of the spacer layer 122 is lower than the carbon concentration of the lower portion of the spacer layer 122 after the surface treatment is complete. Therefore, the properties of the upper portion of the spacer layer 122 and the lower portion of the spacer layer 122 are different after the surface treatment is complete.

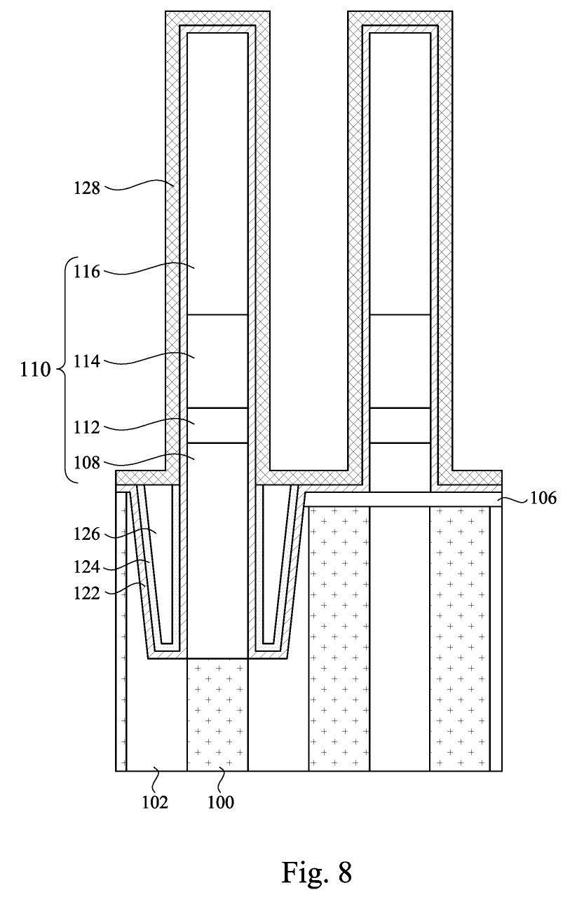

Referring to FIG. 8, a spacer layer 128 is conformally formed over the spacer layer 122 after performing the surface treatment. The spacer layer 128 is made of a dielectric material different from the material of the spacer layer 122. In some embodiments, the spacer layer 128 is made of silicon oxide. In some embodiments, the thickness of the spacer layer 128 is between 4 nm and 6 nm.

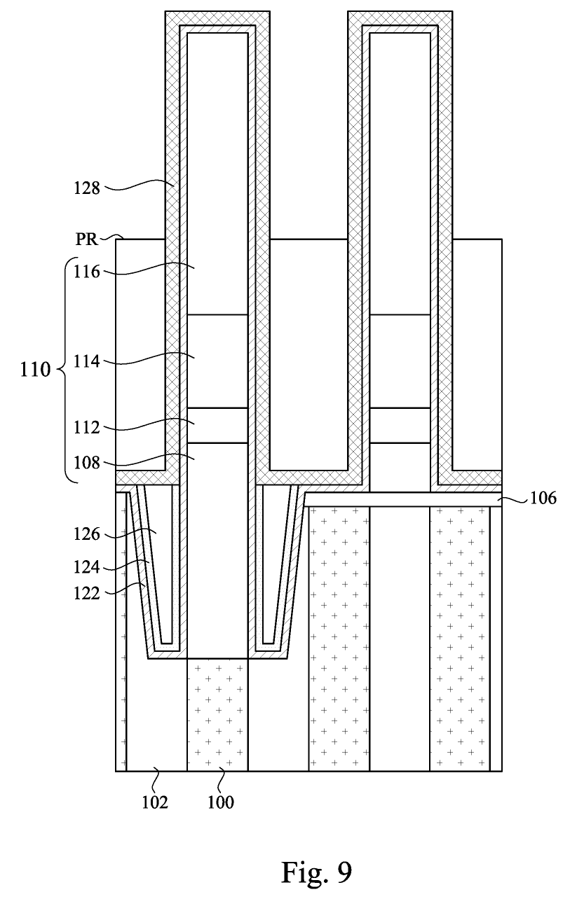

Referring to FIG. 9, a photoresist layer PR is formed over the spacer layer 128 and overfilling the trench T1 between the bit line structures 110, and then the photoresist layer PR is etched back, such that the photoresist layer PR covers the lower portion of the spacer layer 128. The upper portion of the spacer layer 128 is exposed by the photoresist layer PR.

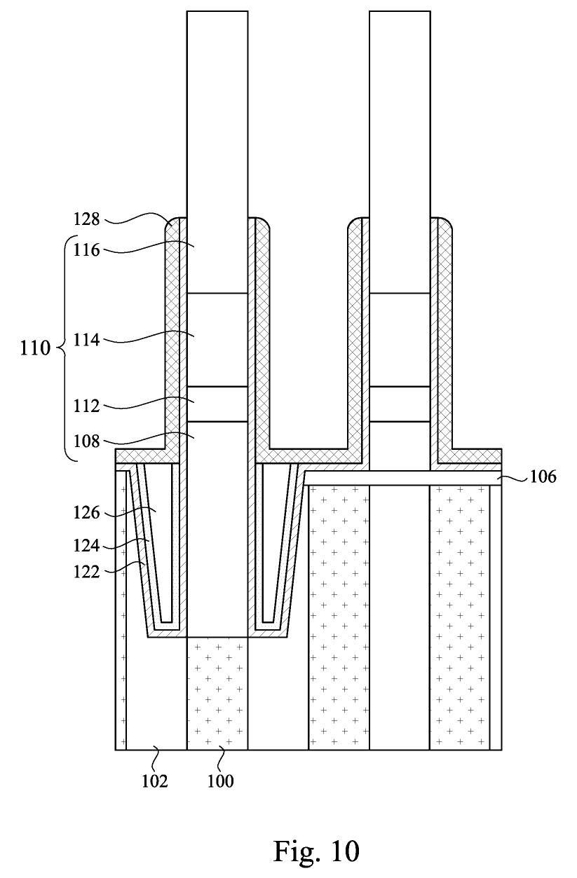

Referring to FIG. 10, an etching process is performed to remove the upper portion of the spacer layer 128 and the upper portion of the spacer layer 122. The upper portion of the spacer layer 128 and the upper portion of the spacer layer 122 are not covered by the photoresist layer PR, so they may be etched by suitable etching process. The etching process has the etching selectivity between oxide-based materials and other materials. In some embodiments, the etching process in FIG. 10 etches silicon oxide faster than etching other materials, such as silicon nitride. In some embodiments, the etching process removes the spacer layer 122 faster as an oxygen concentration of the spacer layer 122 is higher, removes the spacer layer 122 faster as a silicon concentration of the spacer layer 122 is lower, and removes the spacer layer 122 faster as a carbon concentration of the spacer layer 122 is lower. Since the upper portion of the spacer layer 122 has been treated and has high oxygen concentration, the properties of the upper portion of the spacer layer 122 are like silicon oxide. Therefore, when removing the upper portion of the spacer layer 128, it is also easy to remove the upper portion of the spacer layer 122. The removal of the upper portion of the spacer layer 122 leads to a lower aspect ratio of the trench T1 because the opening of the trench T1 is wider. The top end of the spacer layer 122 is lower than a top surface of the bit line structure 110 after the etching process is complete. The top end of the spacer layer 122 is substantially level with the top end of the spacer layer 128 after the etching process is complete. The photoresist layer PR is stripped after the upper portion of the spacer layer 122 and the upper portion of the spacer layer 128 are removed.

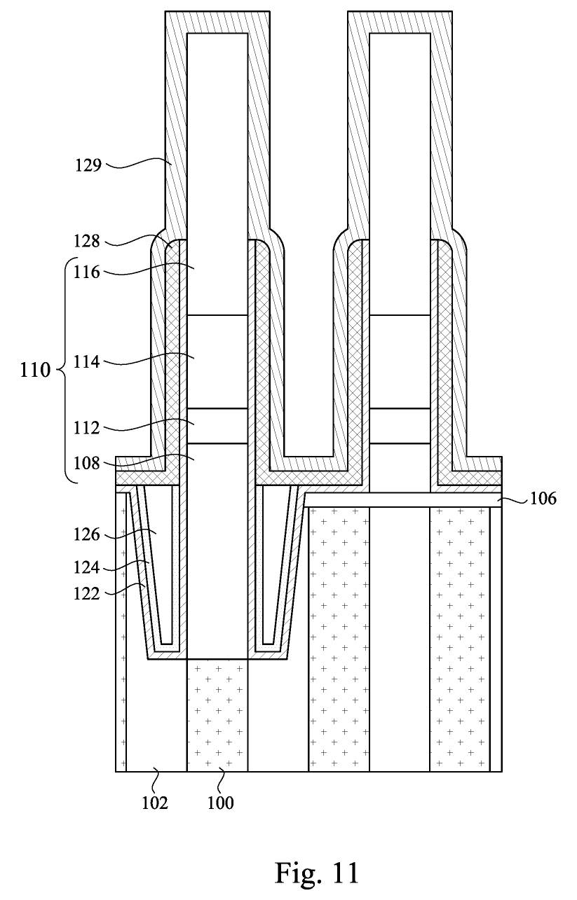

Referring to FIG. 11, a spacer layer 129 is formed conformally over the bit line structures 110 and the spacer layer 128 after removing the upper portion of the spacer layer 122 and the upper portion of the spacer layer 128. The upper portion of the spacer layer 129 is in contact with the cap layer 116 of the bit line structures 110. The spacer layer 128 is cladded by the lower portion of the spacer layer 129 and the spacer layer 122. The interface between the spacer layer 122 and the bit line structure 110 is aligned with the interface between the spacer layer 129 and the bit line structure 110. The spacer layer 129 is made of dielectric material, such as silicon nitride. In some embodiments, the spacer layer 122 and the spacer layer 129 are made of same materials; for example, the spacer layer 122 and the spacer layer 129 are both made of silicon nitride. In some other embodiments, the spacer layer 122 and the spacer layer 129 are made of different materials,; for example, the spacer layer 122 is made of high-k dielectric material, and the spacer layer 129 is made of silicon nitride. The spacer layer 122 is entirely covered and protected by the spacer layer 129. In some embodiments where the spacer layer 122 is made of low-k material, the spacer layer 122 is easily oxidized and will be easily removed in the subsequent processes, which will cause the connections between the conductive layer 114 and the components formed in the subsequent process. Therefore, in the present disclosure, the spacer layer 122 covered by the spacer layer 129 will not be removed in the subsequent process. In some embodiments, the thickness of the spacer layer 122 is between 4 nm and 6 nm. In some embodiments, the spacer layers 122, 128, and 129 may be collectively referred to as a bit line spacer.

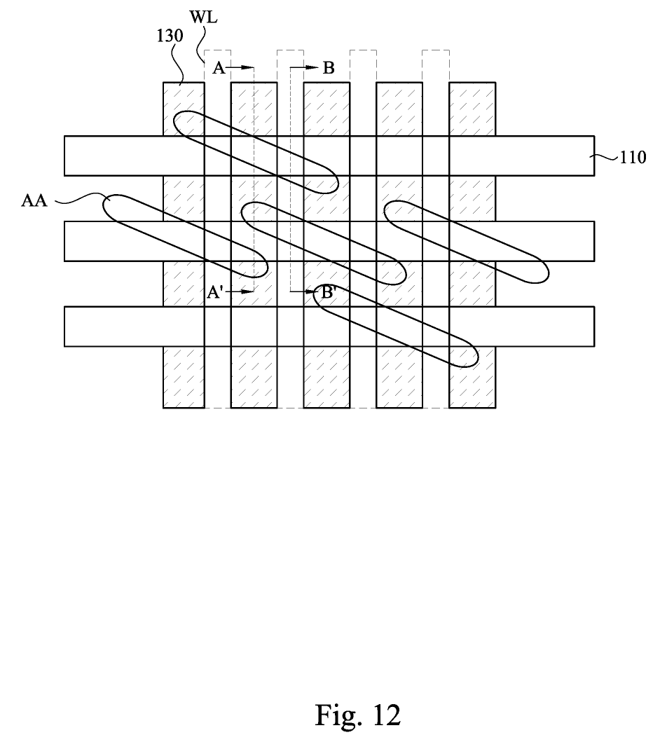

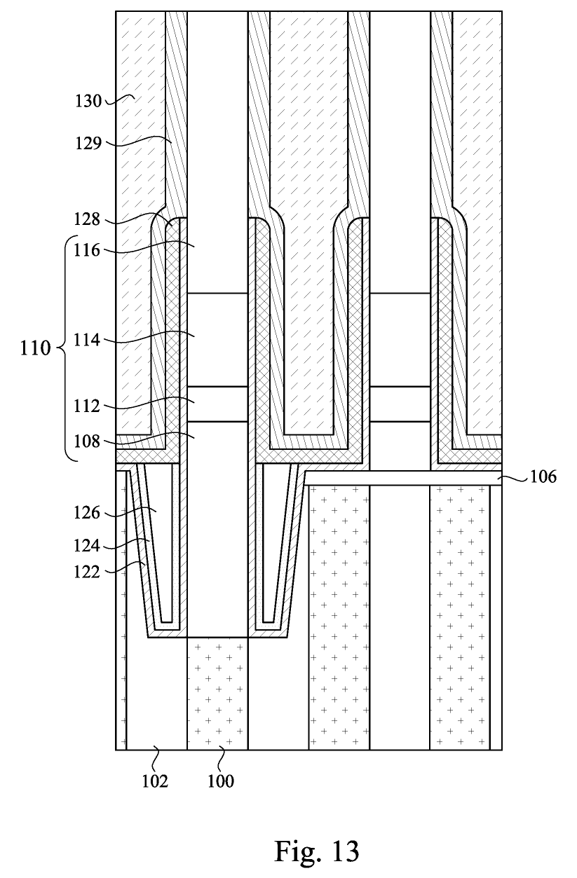

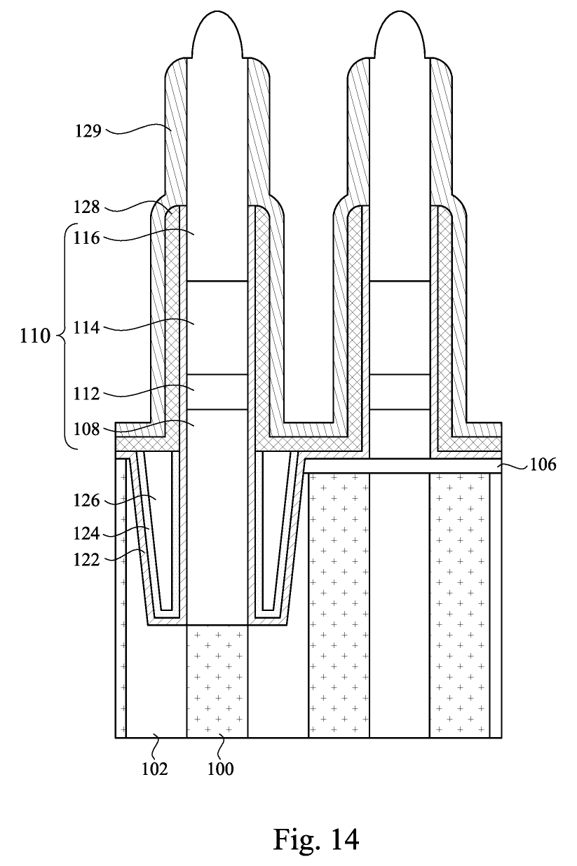

FIG. 12 illustrates a top view of a memory device in some embodiments of the present disclosure. FIGS. 13 and 14 illustrate cross-section views taken along line A-A’ and B-B’ respectively of the memory device in FIG. 12. It is noted that only the bit line structure 110 and the sacrificial layer 130 are illustrated in FIG. 12, and other components are omitted in FIG. 12. Referring to FIGS. 12, 13 and 14, a sacrificial layer 130 is formed over the substrate 100, the bit line structures 110 and overfilling the trench T1. In some embodiments, the sacrificial layer 130 may be formed by spin-on-dielectric coating. Since the upper portion of the spacer layer 122 is removed, the opening of the trench T1 is widened, and thus leads to a better gap fill performance of the sacrificial layer 130.

Subsequently, a planarization process is performed to remove the excess portion of the sacrificial layer 130 until the top of the bit line structures 110 is exposed. Subsequently, the sacrificial layer 130 is patterned, such that a portion of the substrate 100 is covered by the sacrificial layer 130 as shown in FIG. 13, and a portion of the substrate 100 is not covered by the sacrificial layer 130 as shown in FIG. 14. The spacer layer 129 entirely covers the spacer layer 122. Therefore, even if the spacer layer 122 is oxidized in the previous stage, the spacer layer 129 prevents the process of patterning the sacrificial layer 130 from removing the spacer layer 122. The material formed in the subsequent process will be not in contact with the bit line structures 110. After patterning the sacrificial layer 130, the top of the bit line structures 110 are partially etched, and the top of the bit line structures 110 not adjacent to the sacrificial layer 130 becomes a curve. The top of the bit line structures 110 not adjacent to the sacrificial layer 130 is lower than the top of the bit line structures 110 adjacent to the sacrificial layer 130. Partially removing the bit line structures 110 can lower the aspect ratio of the trench T1 between the bit line structures 110, and thus reduce the difficulty of filling the material in the subsequent process. The sacrificial layers 130 is made of dielectric material different from the material of the spacer layer 129. In some embodiments, the sacrificial layers 130 may be made of silicon oxide.

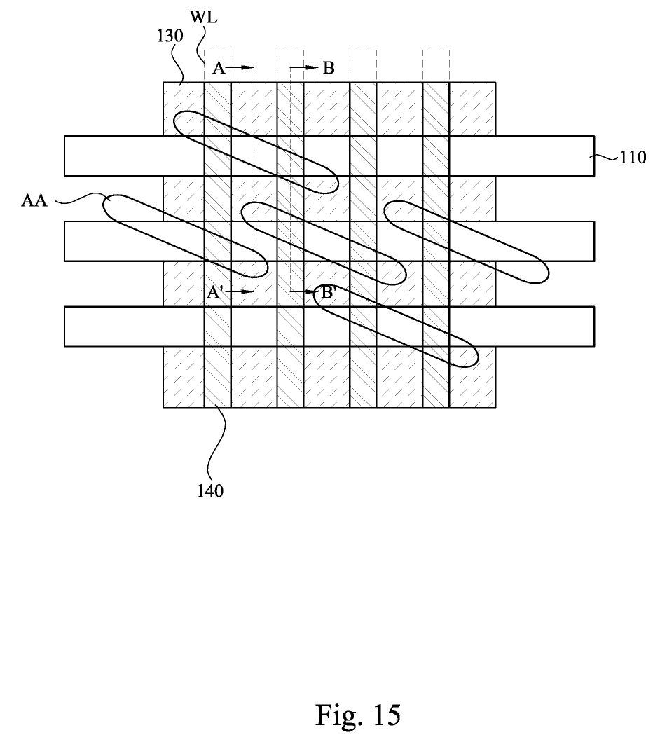

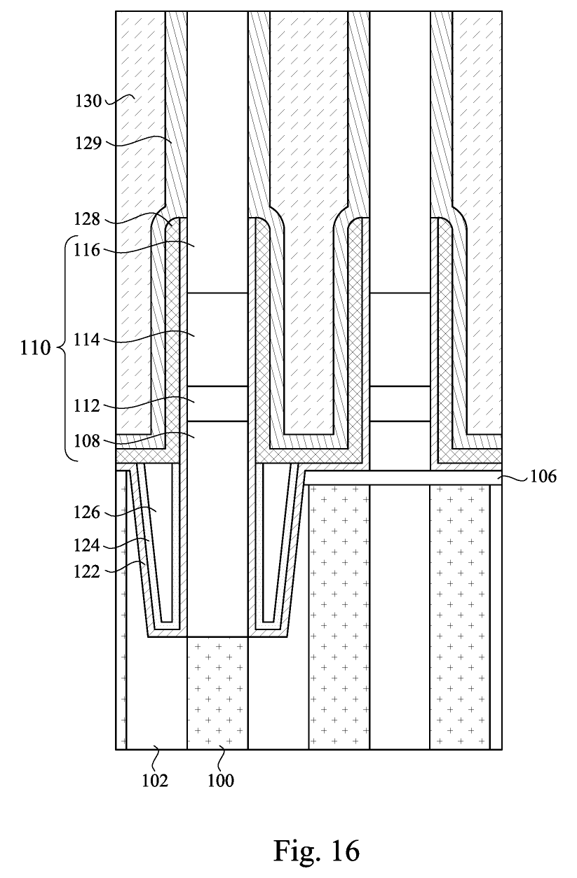

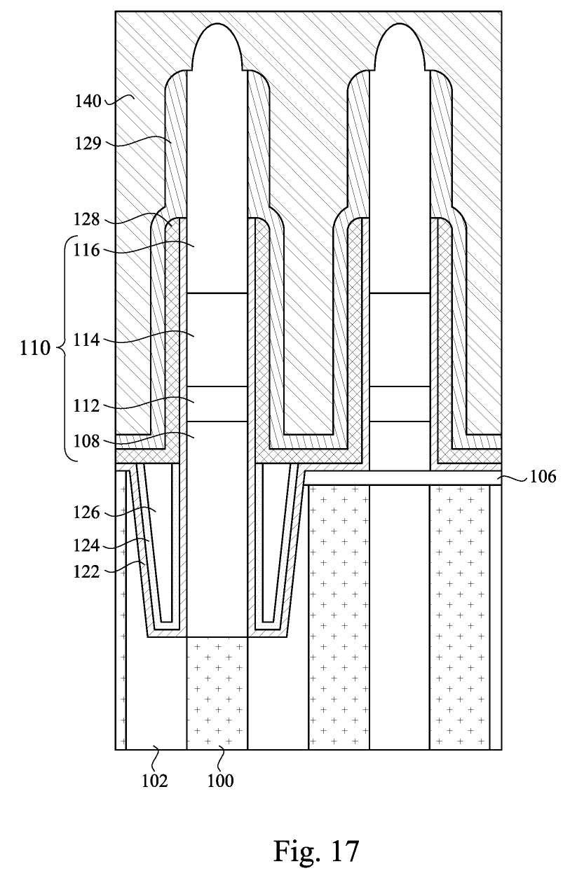

FIG. 15 illustrates a top view of a memory device in some embodiments of the present disclosure. FIGS. 16 and 17 illustrate cross-section views taken along line A-A’ and B-B’ respectively of the memory device in FIG. 15. It is noted that only bit line structure 110, the sacrificial layer 130 and the isolation layer 140 are illustrated in FIG. 15, and other components are omitted in FIG. 15. Referring to FIGS. 15, 16 and 17, the isolation layer 140 is formed overfilling the trench T1 and over the bit line structures 110. In some embodiments, the isolation layer 140 may be formed by low pressure chemical vapor deposition (LPCVD). Since the upper portion of the spacer layer 122 is removed, the opening of the trench T1 is widened, and thus leads to a better gap fill performance of the isolation layer 140.

Subsequently, a planarization process is performed to remove the excess portion of the isolation layer 140 until the top of the bit line structures 110 is exposed. Since the top of the bit line structures 110 not adjacent to the sacrificial layer 130 is lower than the top of the bit line structures 110 not adjacent to the sacrificial layer 130, the top of the bit line structures 110 not adjacent to the sacrificial layer 130 is still covered by the isolation layer 140. The isolation layer 140 is made of dielectric material different from the material of the sacrificial layer 130. In some embodiments, the isolation layer 140 may be made of silicon nitride.

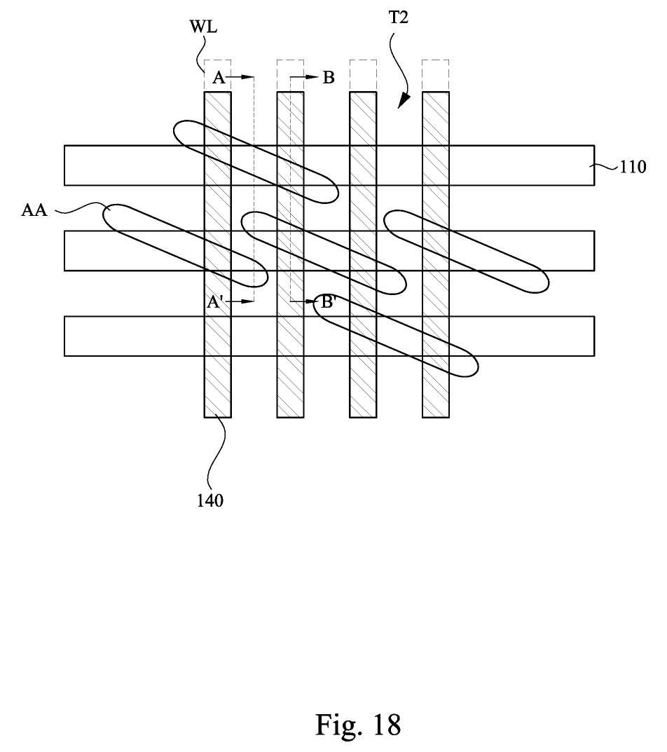

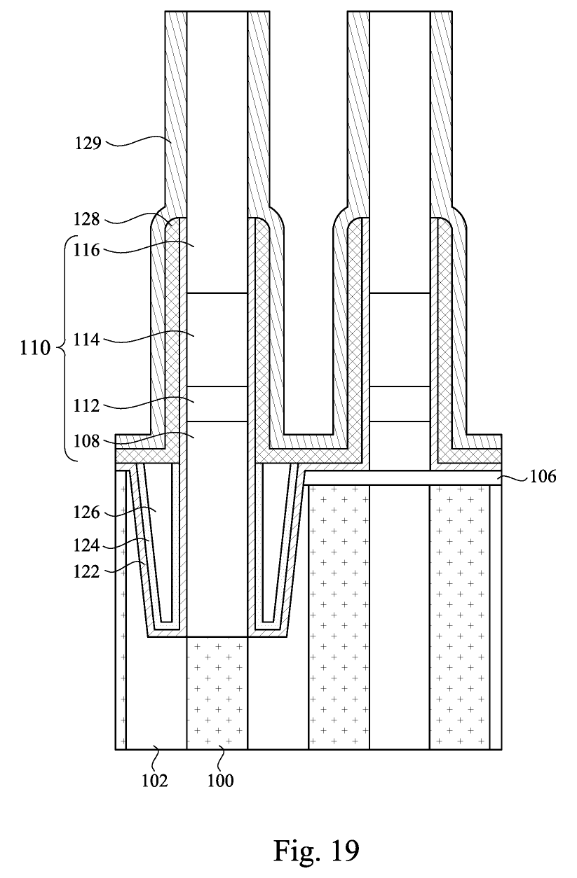

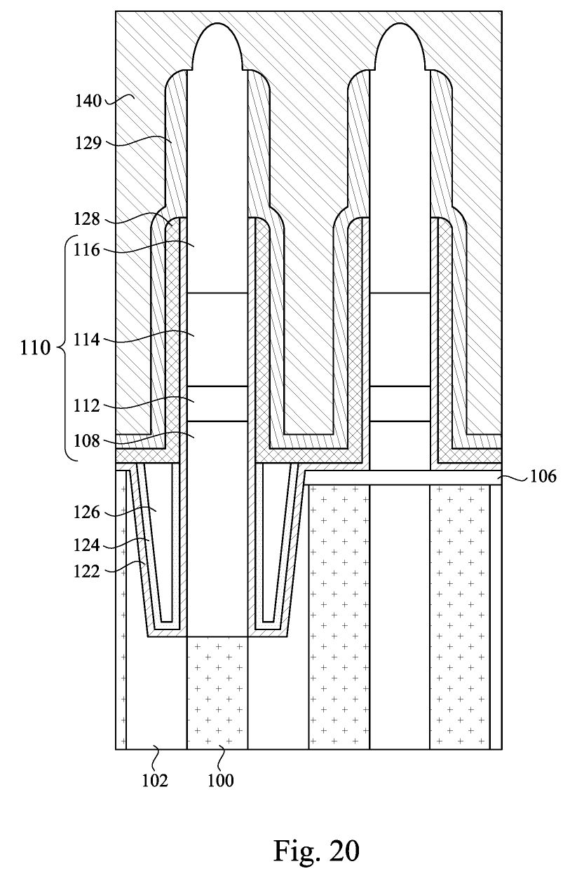

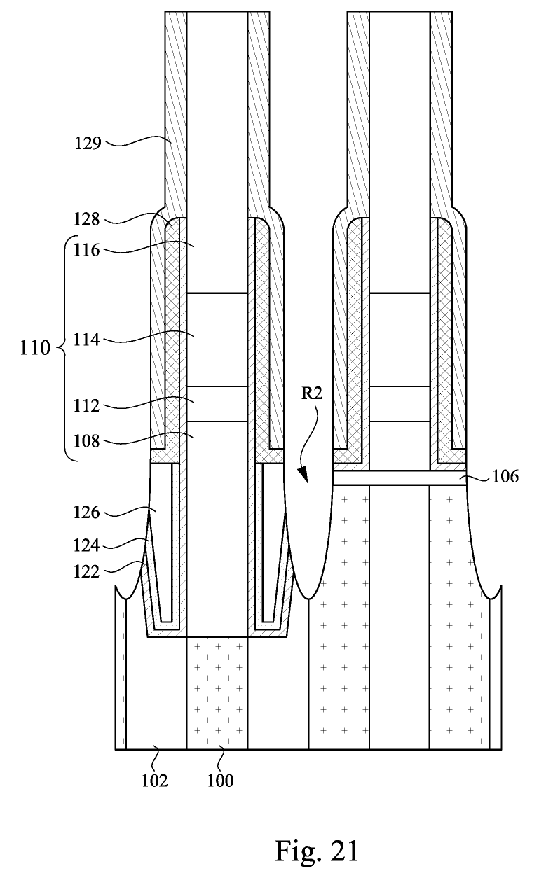

FIG. 18 illustrates a top view of a memory device in some embodiments of the present disclosure. FIGS. 19 and 21 illustrate cross-section views taken along line A-A’ of the memory device in FIG. 18, and FIG. 20 illustrates cross-section views taken along line B-B’ of the memory device in FIG. 18. It is noted that only bit line structure 110 and the isolation layer 140 are illustrated in FIG. 18, and other components are omitted in FIG. 18. Referring to FIGS. 18, 19, and 20, an etching process may be performed to remove the sacrificial layer 130. The sacrificial layer 130 is made of the material different from the material of the spacer layer 129 and the isolation layer 140, and thus a suitable etching process may be chosen to remove the sacrificial layer 130 and substantially not remove the spacer layer 129 and the isolation layer 140. The adjacent isolation layers 140 define a trench T2.

Referring to FIG. 21, an etching process is performed to etch through a portion of the spacer layer 128 and the spacer layer 129 in the trench T2 to form a recess R2 exposing the substrate 100. The spacer layer 122, the stop etch layer 124 and the filling layer 126 in the recess R1 (see FIG. 3) are also partially etched. The other portion of the spacer layer 128 and the spacer layer 129 covered by the isolation layer 140 are not etched.

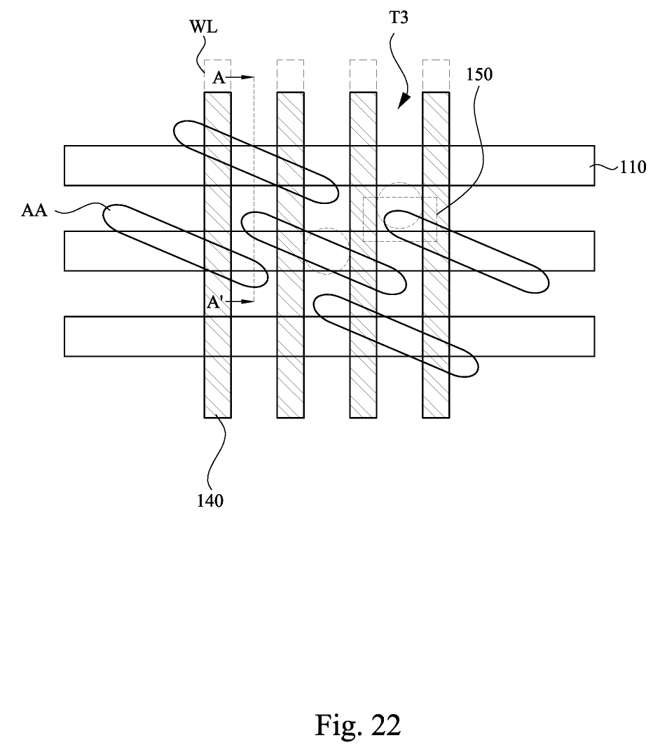

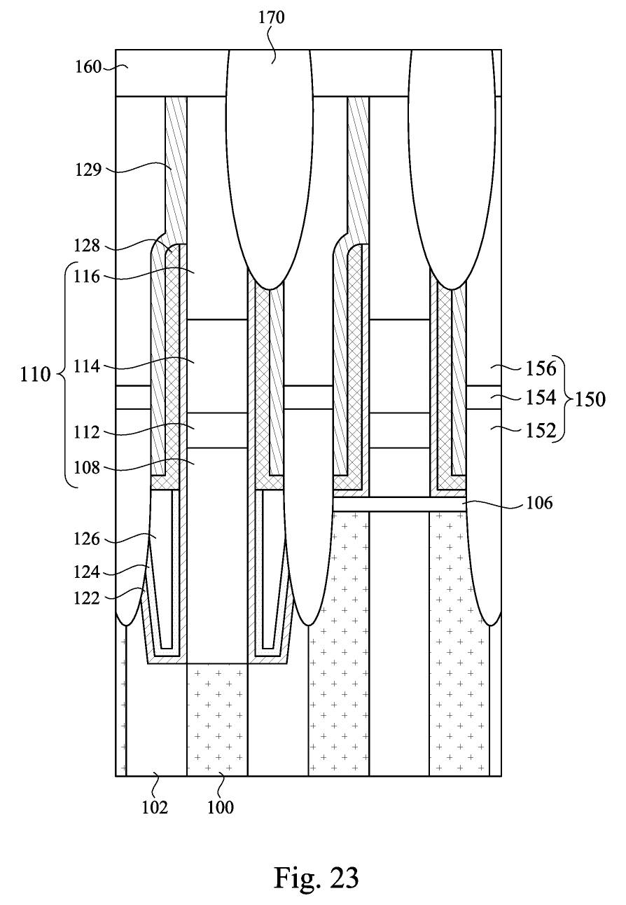

FIG. 22 illustrates a top view of a memory device in some embodiments of the present disclosure. FIG. 23 illustrate a cross-section view taken along line A-A’ of the memory device in FIG. 22. It is noted that only bit line structure 110, the isolation layer 140 and the contact structures 150 are illustrated in FIG. 22, and other components are omitted in FIG. 22. Referring to FIGS. 22 and 23, contact structure 150 are formed adjacent to the bit line structure 110 and in the trench T2. Specifically, the contact structures 150 are formed by sequentially forming a conductive layer 152, a conductive layer 154, and a conductive layer 156 in the trench T2. In some embodiments, the conductive layer 152 may be made of doped poly silicon, the conductive layer 154 may be made of metal silicide, such as CoSi, and the conductive layer 156 may be made of metal, such as tungsten. Subsequently, a landing pad 160 is formed over and in contact with the bit line structures 110 and the contact structures 150, and the landing pad 160 is spaced apart from the spacer layer 122 and the spacer layer 128. The bottom surface of the landing pad 160 is higher than a top end of the spacer layer 122. In some embodiments, the landing pad 160 may be made of metal, such as tungsten. The conductive layer 152 of the contact structure 150 is in contact with the substrate 100, and the contact structure 150 and the landing pad 160 provide the connection between the substrate 100 and the subsequent formed capacitor.

Subsequently, a recess penetrating the landing pad 160 is formed, and isolation structures 170 are formed in the recess. The bottoms of the isolation structures 170 are in contact with the cap layers 116 of the bit line structures 110, the spacer layers 122, 128, 129, and the contact structures 150. The isolation structures 170 are used to isolate adjacent landing pads 160. After the isolation structures 170 are formed, capacitors (not illustrated) are formed over the landing pads 160.

The resulting memory device is illustrated in FIG. 23. The memory device includes a bit line structure 110, a bit line spacer, and a landing pad 160. The bit line spacer is along a sidewall of the bit line structure 110 and includes a spacer layer 122, a spacer layer 128 and a spacer layer 129. The spacer layer 122 is in contact with a lower portion of the sidewall of the bit line structure 110. The spacer layer 128 is along a sidewall of the spacer layer 122. The spacer layer is along a sidewall of the spacer layer 128, and the spacer layer 129 extends to an upper portion of the sidewall of the bit line structure 110. The spacer layer 129 is in contact with a top end of the spacer layer 122. The landing pad 160 is over the bit line structure 110. The spacer layer 129 vertically overlaps the spacer layer 122, and the spacer layer 129 has a portion vertically between the landing pad 160 and the spacer layer 122.

As mentioned above, the present disclosure is used to reduce the aspect ratio of the trench between the bit line structures 110. Therefore, it is easier to fill the material in the trench between the bit line structures 110. Specifically, the aspect ratio of the trench between the bit line structures 110 may be reduced by performing the surface treatment to the spacer layer 122 made of silicon nitride or low-k material along the sidewall of the bit line structure 110. The upper portion of the spacer layer 122 has a higher oxygen concentration accordingly. The upper portion of the spacer layer 122 is able to be removed by the etching process used to remove the spacer layer 128 made of silicon oxide, and the width of the trench between the bit line structures 110 is widened to lower the aspect ratio.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a memory device, comprising:
forming a bit line structure over a substrate;
conformally forming a first spacer layer over the bit line structure;
performing a surface treatment to an upper portion of the first spacer layer, wherein an oxygen concentration of the upper portion of the first spacer layer is higher than an oxygen concentration of a lower portion of the first spacer layer after the surface treatment;
removing the upper portion of the first spacer layer;
forming a contact structure adjacent to the bit line structure; and
forming a landing pad over the contact structure and the bit line structure.

2. The manufacturing method of claim 1, wherein performing the surface treatment comprising:
performing an oxygen-containing plasma treatment or a hydrogen-containing plasma treatment to the upper portion of the first spacer layer.

3. The manufacturing method of claim 1, wherein a silicon concentration of the upper portion of the first spacer layer is lower than a silicon concentration of a lower portion of the first spacer layer after the surface treatment.

4. The manufacturing method of claim 1, wherein the surface treatment is performed with a tilted angle.

5. The manufacturing method of claim 1, further comprising:
conformally forming a second spacer layer over the first spacer layer after performing the surface treatment;
forming a photoresist layer covering a lower portion of the second spacer layer, wherein an upper portion of the second spacer layer is exposed by the photoresist layer; and
removing the upper portion of the second spacer layer.

6. The manufacturing method of claim 5, wherein the upper portion of the second spacer layer and the upper portion of the first spacer layer are removed at the same time.

7. The manufacturing method of claim 5, further comprising:
conformally forming a third spacer layer over the bit line structure and the second spacer layer after removing the upper portion of the first spacer layer and the upper portion of the second spacer layer, wherein an upper portion of the third spacer layer is in contact with the bit line structure.

8. The manufacturing method of claim 7, wherein the second spacer layer is cladded by a lower portion of the third spacer layer and the first spacer layer.

9. The manufacturing method of claim 1, wherein the landing pad is spaced apart from the first spacer layer.

10. The manufacturing method of claim 1, wherein a bottom of the landing pad is higher than a top end of the first spacer layer.

11. A memory device, comprising:
a bit line structure;
a bit line spacer along a sidewall of the bit line structure and comprising:
a first spacer layer in contact with a lower portion of the sidewall of the bit line structure;
a second spacer layer along a sidewall of the first spacer layer; and
a third spacer layer along a sidewall of the second spacer layer, wherein the third spacer layer extends to an upper portion of the sidewall of the bit line structure; and
a landing pad over the bit line structure.

12. The memory device of claim 11, wherein the third spacer layer is in contact with a top end of the first spacer layer.

13. The memory device of claim 11, wherein an interface between the first spacer layer and the bit line structure is aligned with an interface between the third spacer layer and the bit line structure.

14. The memory device of claim 11, wherein a top end of the first spacer layer is substantially level with a top end of the second spacer layer.

15. The memory device of claim 11, wherein the landing pad is spaced apart from the first spacer layer.

16. The memory device of claim 11, wherein a bottom surface of the landing pad is higher than a top end of the first spacer layer.

17. The memory device of claim 11, wherein a top end of the first spacer layer is lower than a top surface of the bit line structure.

18. The memory device of claim 11, wherein the third spacer layer vertically overlaps the first spacer layer.

19. The memory device of claim 11, wherein the third spacer layer has a portion vertically between the landing pad and the first spacer layer.

20. The memory device of claim 11, wherein the first spacer layer and the third spacer layer are made of different materials.
